(19) United States
(12) Patent Application Publication
(10) Pub. No.: US 2005/0035306 A1
(43) Pub. Date: Feb. 17, 2005

(54) Focused charged particle beam apparatus

(76) Inventor: Kouji Iwasaki, Chiba-shi (JP)

Correspondence Address: ADAMS & WILKS, 31st FLoor, 50 Broadway, New York, NY, 10004, US

(21) Appl. No.: 10/635,958

(22) Filed: Aug. 7, 2003

(30) Foreign Application Priority Data
Aug. 9, 2002 (JP) 2002-232293

(51) Int. Cl. H01J 37/31

(52) U.S. Cl. 250/492.2; 250/442.11

(57) ABSTRACT

In order to enable perpendicular processing of a slice in all directions about a lens optical axis, a focused charged particle beam of the present invention is provided with a tilt mechanism capable of tilting in two axial directions below a three dimensional X, Y, Z drive mechanism, as sample stage drive means. In this way, when carrying out correction processing of a clear defect of a penetrating structure in an electron beam exposure mask, it is possible to accurately carry out perpendicular processing of pattern surfaces in all directions.

### BACKGROUND OF THE INVENTION

The present invention relates to technology for processing a fine detailed stencil structure such as a stencil mask using electron beam projection lithography (EPL).

high densification and systemization of LSIs has become widespread because of the recent small scale/high performance of electronic devices such as personal computers and portable telephones. Line widths for drawing circuit patterns currently in operation having a few million elements crammed onto a semiconductor chip of only a few millimeters square have also progressed from the micron to the nano order, and in order to realize this, technological development in the field of lithography has been unfolding. Up to now, the mainstream of lithography has been optical lithography technology, but the wavelength of light used has also become extremely short as the patterns become ever finer, and processing has also been carried out using short wavelength lasers. However, with this processing also there is a problem with respect to the optical systems and resist, and fine patterning using light exposure devices has gradually reached its limit. Therefore technology for radiating electron beams and extremely short ultraviolet rays instead of light has extremely good future prospects.

Electron Beam Projection Lithography (EPL) has been gathering attention as a manufacturing method for devices having nodes in the order of 100 nm to 50 nm. A stencil reticule mask is one example of an EPL mask. As shown in FIG. 5, the EPL stencil reticule mask comprises an Si membrane 21 for electron scattering (thickness 2.0 μm) and holes for allowing electrons to pass. Generally, a silicon wafer is processed to make an EPL stencil reticule mask, holes 22 are made in a region equivalent to one reticule, and a pattern is formed with a penetrating structure in the bottom section of the region. With this mask, a 100 kV electron beam from an electron lens barrel irradiates the bottom surface of the stencil reticule mask 1 with light rays coming parallel from above. The electron beam 2 is shielded by the bottom section except at penetrated sections, and the electron beam 2 that has passed through the penetrating sections is narrowed and projected onto the surface of the resist 4 using an electron lens 3, and a pattern represented by the penetrating structure is transferred and exposed.

The presence or absence, location and shape of defects in a mask for electron beam exposure used in this way is determined by transparent image observation using an electron beam device, such as an electron microscope. An electron beam mask in which defects are discovered can be corrected using a focused ion beam (FIB) device like that shown in FIG. 4. This FIB device irradiates a sample surface using an ion optical system to accelerate and focus ions emitted from an ion source 12 into a focused ion beam 5. At that time, irradiation is turned ON and OFF using blanking electrodes, and also a function is provided capable of X-Y scanning of the irradiation position using deflection electrodes. A mechanism for three-dimensional X, Y and Z drive, rotational drive and tilt drive is also provided on a sample holder 15 on a sample stage 6, so as to be able to adjust the position and angle at which the FIB irradiates a sample 11. Correction processing includes opaque defect correction for removing attached matter 7 by irradiating an FIB 5 and sputter etching, as shown on the left side of FIG. 3, and clear defect correction for adding a deposition film 8 at a defect section by irradiating an FIB 5 to a defect section of a pattern while spraying source material gas from a gas gun 9 to perform ion beam induction deposition, as shown in the right side of FIG. 3. In the drawing, an example is shown of carbon deposition where phenanthrene etc. is the source gas. An FIB irradiates the surface of an electron beam exposure mask (sample surface) so as to scan the surface, secondary charged particles (for example, secondary electrons, secondary ions etc.) emitted from the sample surface are detected using a secondary charged particle detector 14 arranged close to the sample surface, a scanning ion microscope (SIM) image is obtained from information about the sample surface, location and shape of defects is determined, the state of progress of processing is observed, shape confirmation after defect correction is carried out, and it is determined that the processing has achieved its purpose and is therefore complete.

In a fine processing device using a focused charged particle beam, such as an FIB device, strength of the focused charged particle beam is not uniform throughout the cross section of the beam, and since there is usually a normal distribution, a phenomenon arises where, due to the influence of the beam fringe, the upstream side of the beam is significantly attenuated, and even if beam incidence is vertical, a processed cross section is not vertical. If the opaque defect 7 shown on the left side of FIG. 3 is subjected to sputtering using the FIB 5 from above, cutting away is performed along the dotted line in the drawing, and the processed surface takes on a tapered shape, which is not what was intended. The dimensions of an electron beam exposure mask 1 are becoming increasingly fine, and correction accuracy must also be further improved. As a correction error, the inclination of a cross section due to this correction can not be ignored. For example, in the case of an Si membrane 2 μm thick, with an inclination angle of 2 degrees, the dimensional error of a mask rear surface would become about 70 nm. With EPL, since at the time of exposure there is projection to ¼ of the size, in forming a 50 nm pattern the mask pattern becomes 200 nm or less. Under conditions such as these, a dimensional error due to inclination of a pattern having a penetrating structure is a problem that can not be ignored. It depends on the mask pattern size, but inclination angle should be a maximum of ±1 degree or less, and if possible kept to 0.5 degrees or less.

In processing using an FIB device, up to now, processing perpendicular to a cross section has been important. For example, in Japanese Patent Laid-open No. Hei. 4-76437, there is disclosed processing where, at the time of processing a sample for a transmission electron microscope (TEM) for extremely thin plate situations using an FIB device, the sample is tilted a few degrees and etched, and then a TEM observation surface is processed perpendicularly. This processing is perpendicular to both sides of the observation surface to ensure that thickness is uniform because if the sample does not have a uniform thickness there will be places that can be observed using a TEM and places that can not be observed using a TEM. Correction of an electron beam exposure mask using an FIB is also required to be carried out perpendicular to the processing surface in the same way as the FIB processing of the TEM sample. The reason for this is that if it is not perpendicular to the mask cross section, a thin tapered section will pass an electron beam, there will be exposure up to unnecessary sections and there will be the disadvantage that it will not be possible to form a desired pattern. Accordingly, although it is necessary to make the process cross section of the mask perpendicular, even if an electron beam exposure mask is inclined, as in TEM sample processing, and the process cross section made perpendicular, the pattern of a mask having a penetrating structure does not have a process surface where the two sides are parallel surfaces, as with TEM sample processing, and all surfaces through 360° are taken. In this case, it is necessary to tilt the sample stage corresponding to all surfaces, but a sample stage of a conventional FIB fine processing device has a 5 axis stage (XYZRT), as described above, and the direction of tilt of the sample is in one direction. In the case of slice processing, such as TEM sample processing, with the capability of tilt in one direction there is no problem, and the sample can be handled. However, in the case of handling processing to form patterns in various directions, such as an electron beam exposure mask, with tilt capability in only one direction, it is necessary to frequently move the sample during processing. In particular, many rotation functions are utilized, which means that tilting the mask and carrying out processing to form a perpendicular surface is practically impossible.

The object of the present invention is to provide a focused ion beam device capable of easily enabling accurate perpendicular processing of pattern surfaces obtained in all directions without any difficulty, when performing correction processing for pattern defects of a penetrating structure in an electron beam exposure mask, and to enable faithful EB exposure on a mask.

### SUMMARY OF THE INVENTION

A focused charged particle beam device of the present invention comprises a focused charged particle beam generating section, made up of a charged particle source, a focusing lens system for focusing a charged particle beam emitted from the charged particle source, and a blanking electrode for turning the charged particle beam ON or OFF, a deflection electrode for deflection scanning of the focused charged particle beam, a sample stage having drive means for adjusting beam irradiation position and angle, and a gas gun for spraying gas for deposition or assist etching, wherein the sample stage drive means is provided with a mechanism capable of tilting in two axial directions, X and Y, in order to enable processing of a slice in all directions about the lens optical axis

The focused charged particle beam of the present invention has a mechanism capable of tilting in two axial directions, X and Y, mounted below a mechanism capable of movement in three dimensions, X, Y and Z and by having a mechanism capable of setting a sample surface in a tilt range from perpendicular to a few degrees with respect to the focused charged particle beam, it is possible to carry out processing of a slice accurately and perpendicularly in all directions for a pattern of a penetrating structure of an electron beam exposure mask, and it is possible to do away with a rotational drive mechanism, in a mask fine processing device.

A focused charged particle beam device of the present invention, comprising means for data storage of a processing correction angle α for a charged particle beam used, and means for controlling setting of the a sample tilt angle to 90°+α based on data α, can easily carry out perpendicular processing of a slice in all directions for a pattern of a penetrating structure for an electron beam exposure mask.

### BRIEF DESCRIPTION OF THE DRAWINGS

FIG. 1A and FIG. 1B are drawings for describing a two-axis tilt drive mechanism of the present invention.

FIG. 2A and FIG. 2B are drawings comparing related art processing using a focused ion beam (with no sample tilting) and processing using the present invention (with sample tilting).

FIG. 3 is a drawing showing opaque defect correction and clear defect correction using a focused ion beam device.

FIG. 4 is a drawing showing the basic structure of a focused ion beam device.

FIG. 5 is a drawing for describing a device manufacturing method using an electron beam exposure method.

### DETAILED DESCRIPTION OF THE INVENTION

As described above, the present invention provides a focused ion beam device capable of accurate perpendicular processing of pattern surfaces obtained in all directions without any difficulty, when performing correction processing for pattern defects of a penetrating structure in an electron beam exposure mask. Conventionally, it would be normal to carry out this type of fine correction processing using an FIB device, and since an ion beam has a normal power distribution, the process surface had a tapered shape. To solve this, it has been considered to carry out processing by tilting the sample, but it is difficult to handle a sample with processing surfaces in all directions using only a single axis tilt capability. By providing 5 axis capability, namely movement of the sample stage in three dimensions, XYZ, rotation R, and tilt C, in the related art FIB device, theoretically a desired tilt angle is achieved using the C mechanism, and if the R mechanism is used it is possible to perpendicularly process a slice in all directions for a pattern of a penetrating structure for an electron beam exposure mask. However, if this is practically implemented, processing locations that are not on the rotational axis suffer from positional deviation due to the rotational drive, time and effort are wasted in operating a drive mechanism to correct this positional error. Taking into account the fact that in practical terms this is unrealistic the present invention has been conceived to arrange a two axis tilt (double tilt) mechanism at the lowest position in a sample stage drive mechanism, and to have a mechanism capable of realizing tilt in all directions with respect to a lens optical axis in a state where it is difficult for positional error to arise.

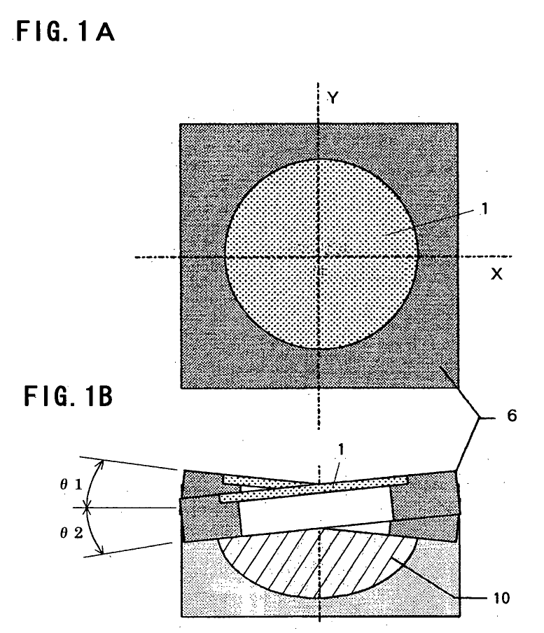

The basic structure of the present invention is shown in FIG. 1A and FIG. 1B. FIG. 1A is a plan view of a sample stage 6 looking from a beam irradiation direction, and FIG. 1B is a cross sectional view of the sample stage 6 looking from the side direction. Orthogonal X and Y axes are shown in the plan view, but these axes are set so as to align with the sample surface, and the point at which they cross is set to align with the optical axis of a lens optical system. This is in order to ensure that there is no positional slip of the sample due tilt operations about the axis. The present invention has this mechanism arranged at the lowest stage of a sample stage drive mechanism. In this way, it is made possible to tilt the sample surface in all directions around the lens optical system, and at the same time there is no deviation of the crossing point, being a central part if the sample, from the beam irradiation position (on the axis of the lens optical system) even if the sample is tilted. The processing position of the sample surface is not always the center of the sample, but by having the X, Y drive mechanism on the tilt mechanism, an X-Y sliding surface will be tilted at the same angle, and no matter where the processing location is, if that X, Y coordinate position is moved to it will be possible to hold the location at the same beam irradiation position.

The maximum tilt angles θ 1 and θ 2 can have absolute values of at least about 5°.

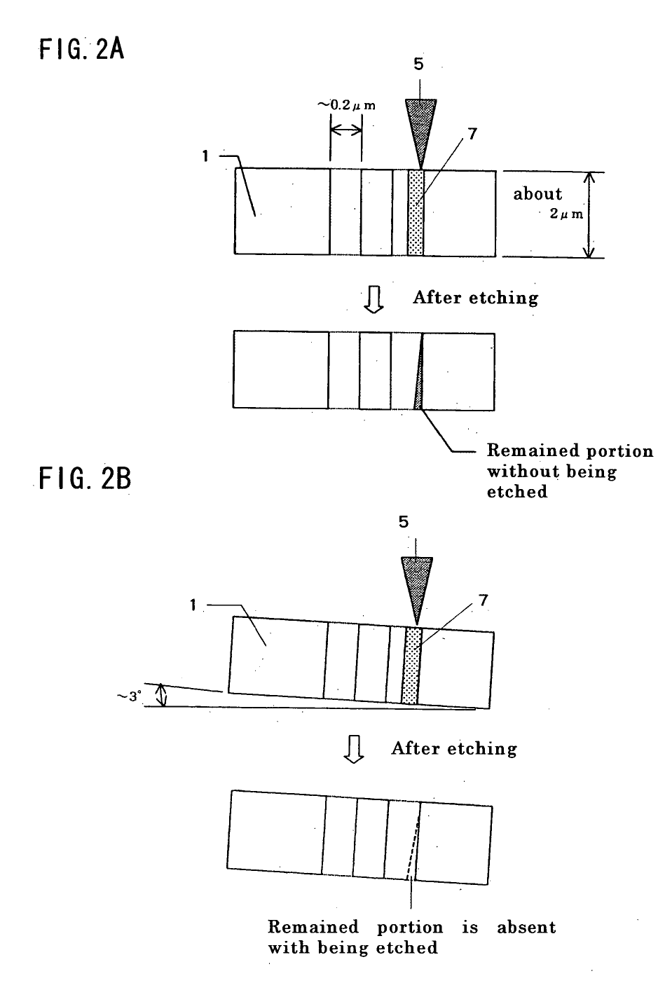

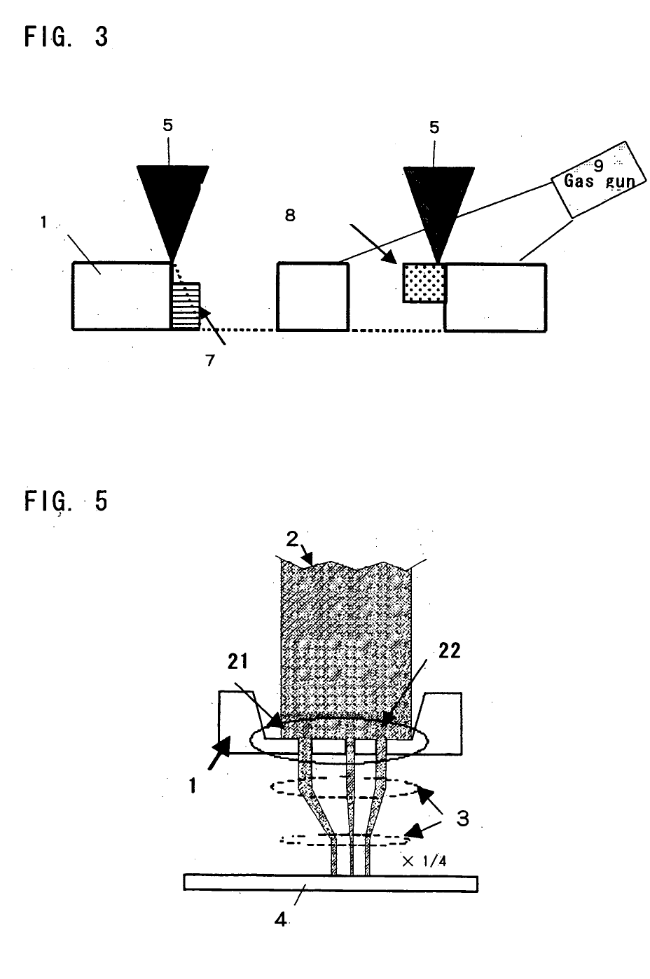

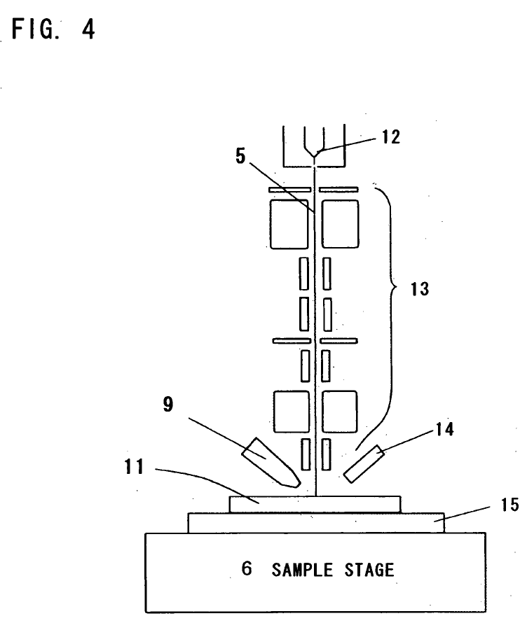

FIG. 2A and FIG. 2B show comparison of processing results for perpendicular processing of a slice of a pattern for an electron beam exposure mask 1 having a penetrating structure with the related art device and with the device of the present invention. With the related art structure shown in FIG. 2A, if an FIB 5 is irradiated with the sample surface orthogonal to the optical axis of the lens optical system and correction processing carried out by sputter etching of an opaque defect section shown by dots in the drawing, since the FIB 5 has a normal strength distribution, even though a beam that is subjected to the accumulative effects of a fringe section at an upstream side is perpendicular, as shown in FIG. 2A, there is a tapered remaining portion after sputter etching has been carried out. On the other hand, if the device of the present invention is used, as shown in FIG. 2B, the process surface is tilted by an amount corresponding to a taper angle based on the sputtering characteristics of the FIB 5 used (here it is about 3°), and if the FIB 5 is then irradiated to carry out correction processing of the opaque defect section 7 shown by dots in the drawing by sputter etching, desired surface etching is realized. This is because although the FIB 5 performs sputtering to process the same tapered shape, the surface to be processed is itself not perpendicular, and is tilted by the taper angle. The object of processing in this case is an electron beam exposure mask having a penetrating structure. The double tilt mechanism of the present invention can handle tilt surface directions for all surfaces of through holes, which means that it is possible to carry out processing in a cross sectional shape that is the same from the surface side to the rear surface side of a mask.

The above description has been directed to correction processing of an electron beam exposure mask using an FIB device. However, this is not limiting, and it is also possible to carry out similar processing using an electron beam, by providing a function for spraying gas for assist etching of a mask material and deposition gas from a gas gun. Electrons are different from ions in that they have a small mass, which means that although it is not possible to perform sputter etching using the electrons themselves, it is possible to remove opaque defects using gas assist etching. Since a focused electron beam also has a normal power distribution, the same as for a focused ion beam, the phenomenon of the processed surface becoming taper-shaped is also the same. Accordingly, the present invention can be understood from the basic concept of a focused charged particle beam device. [First Embodiment]

The main element of the present invention is the drive mechanism for the sample stage. This embodiment is shown in the following. An inclinable stage is adopted which is capable of handling at any 360° direction with two orthogonal axes as a center, and a high precision 3-axis stage (XYZ) is mounted on the inclining stage. As shown in FIG. 1B, the double tilt mechanism adopted with this embodiment has a stage side hemispherical protuberance fitted into a hemispherical indentation formed in a fixed body section, to form a hemispherical slide mechanism 10, and also comprises a tilt drive mechanism for two orthogonal axes. A 3-axis X, Y Z stage provided with a laser interferometer so as to be capable of high speed high precision operation is adopted. Also, respective processing correction angles α corresponding to types of FIB having different acceleration, beam current values etc., are stored in advance in storage means of a computer as data. Two actuators are provided in the 2-axis tilt drive source, and a processing correction angle α corresponding to the type of FIB used is read out from the storage means, and the actuators are controlled so that an angle defined by a correction surface and an incident beam is always 90°+α.

Since the focused charged particle beam device of the present invention comprises a focused charged particle beam generating section, made up of a charged particle source, a focusing lens system for focusing a charged particle beam emitted from the charged particle source, and a blanking electrode for turning the charged particle beam ON or OFF, a deflection electrode for deflection scanning of the focused charged particle beam, a sample stage having drive means for adjusting beam irradiation position and angle, and a gas gun for spraying gas for deposition or assist etching, with the sample stage drive means comprising a mechanism capable of tilting in two axial directions, X and Y, and a mechanism capable of movement in three dimensions, X, Y and Z, it is possible to tilt in all directions.

Since the focused charged particle beam device of the present invention has a mechanism capable of movement in three dimensions, X, Y and Z mounted below a mechanism capable of tilting in two axial directions, X and Y, and has a mechanism capable of setting a sample surface in a tilt angle range from perpendicular to a few degrees with respect to the focused charged particle beam, it is possible to correct an clear defect of an electron beam exposure mask, and to make a mask process surface perpendicular. In this way, faithful electron beam exposure is enabled on a mask.

Because the focused charged particle beam device of the present invention comprises means for data storage of a processing correction angle α for a charged particle beam used, and means for controlling so as to set an angle defined by a mask correction surface and an incident beam to 90°+α based on data α, it is possible to easily carry out perpendicular processing of a slice in all directions for a an electron beam exposure mask pattern having a penetrating structure.

Also, since the focused ion beam device of the present invention adopts an electron beam as the focused charged particle beam device, and is provided with a function for spraying gas for assist etching of a mask material, or deposition gas, from a gas gun, it is possible to carry out correction processing of a fine stencil structure using a focused electron beam device that switched FIB devices, and it is made possible to correct a clear defect of an electron beam exposure mask with an electron beam, and to make the mask process surface perpendicular. In this way, faithful electron beam exposure is enabled on a mask.

1. A focused charged particle beam device, comprising a focused charged particle beam generating section, made up of a charged particle source, a focusing lens system for focusing a charged particle beam emitted from the charged particle source, and a blanking electrode for turning the charged particle beam ON or OFF, a deflection electrode for deflection scanning of the focused charged particle beam, a sample stage having drive means for adjusting beam irradiation position and angle, and a gas gun for spraying gas for deposition or assist etching, wherein the sample stage drive means comprises a mechanism capable of tilting in two axial directions, X and Y, and a mechanism capable of movement in three dimensions, X, Y and Z, to enable tilting in all directions.

2. The focused charged particle beam of claim 1, wherein a mechanism capable of movement in three dimensions, X, Y and Z is mounted below a mechanism capable of tilting in two axial directions, X and Y, and a focused ion beam is adopted as the focused charged particle beam, wherein by having a mechanism capable of setting a sample surface in a tilt angle range from perpendicular to a few degrees with respect to the beam, it is made possible to carry out processing of a slice accurately and perpendicularly in all directions for a pattern of a penetrating structure of an electron beam exposure mask.

3. The focused charged particle beam device of claim 1, comprising means for data storage of a processing correction angle α for a charged particle beam used, and means for controlling setting of the a sample tilt angle to 90°+α based on data α, capable of carrying out perpendicular processing of a slice in all directions for an electron beam exposure mask pattern having a penetrating structure.

4. The focused ion beam device of claim 1, provided with a function for spraying gas for assist etching of a mask material, or deposition gas, from a gas gun, adopting an electron beam as the focused charged particle beam device.
